(19) United States
(12) Patent Application Publication
(10) Pub. No.: US 2015/0092352 A1
(43) Pub. Date: Apr. 2, 2015

(54) Thermal Interface Solution With Reduced Adhesion Force

(71) Applicant: International Bus9iness Machines Corporation, Armonk, NY (US)

(72) Inventors: Timothy J. Chainer, Armonk, NY (US); Paul W. Croteus, Armonk, NY (US); Michael Gaynes, Armonk, NY (US); Shawn Hall, Armonk, NY (US); Shurong Tian, Armonk, NY (US)

(73) Assignee: International Business Machines Corporation, Armonk, NY (US)

(21) Appl. No.: 14/040,704

(22) Filed: Sep. 29, 2013

(51) Int. Cl. H05K 7/20; H01L 23/34; H01L 23/00

(52) U.S. Cl. CPC H05K 7/20509; H01L 24/83; H01L 23/34
USPC 361/720; 438/122

(57) ABSTRACT

An article of manufacture comprises a composite, layered, and compressible TIM differentially adhered to a heat-spreader surface and a heat-source surface, such as a circuit card, where at least one of the surfaces comprises an uneven surface, and the TIM is compressively bonded to the uneven surface. The adhesive strength of the TIM to the heat-spreader surface is unequal to the adhesive strength of the TIM to the heat-source surface, and is adjusted so that the heat-spreader surface and the heat-source surface can be separated without damaging the heat-source surface. A process comprises manufacturing the article of manufacture.

### FIELD OF THE INVENTION

The field of the invention in one aspect comprises a composite, layered, and compressible thermal interface material (TIM) to provide differential adhesion of the surface of a heat-spreader to the surface of a heat-source, (i.e., heat-source surface) where at least one of the surfaces comprises an uneven surface. One embodiment of the invention comprises a breakaway structure for heat susceptible microcircuit elements of different heights comprising such elements extending from a surface and adhered to a heat-spreader surface by the TIM.

### BACKGROUND OF THE INVENTION

The so-called “silicon revolution” brought about the development of faster and larger computers beginning in the early 1960s with predictions of rapid growth because of the increasing numbers of transistors packed into integrated circuits with estimates they would double every two years. Since 1975, however, they doubled about every 18 months.

An active period of innovation in the 1970s followed in the areas of circuit design, chip architecture, design aids, processes, tools, testing, manufacturing architecture, and manufacturing discipline. The combination of these disciplines brought about the VLSI era and the ability to mass-produce chips with 100,000 transistors per chip at the end of the 1980s, succeeding the large scale Integration (“LSI”) era of the 1970s with only 1,000 transistors per chip. (Carre, H. et al. “Semiconductor Manufacturing Technology at IBM”, IBM J. RES. DEVELOP., VOL 26, no. 5, September 1982). Mescia et al. also describe the industrial scale manufacture of these VLSI devices. (Mescia, N. C. et al. “Plant Automation in a Structured Distributed System Environment,” IBM J. RES. DEVELOP., VOL. 26, no. 4, July 1982).

The release of IBM's Power6™ chip in 2007, noted “miniaturization has allowed chipmakers to make chips faster by cramming more transistors on a single slice of silicon, to the point where high-end processors have hundreds of millions of transistors. But the process also tends to make chips run hotter, and engineers have been trying to figure out how to keep shrinking chips down while avoiding them frying their own circuitry.” (http://www.nytimes.com/reuters/technology/tech-ibm-power.html?pagewanted=print (Feb. 7, 2006))

Technology scaling of semiconductor devices to 90 nm and below has provided many benefits in the field of microelectronics, but has introduced new considerations as well. While smaller chip geometries result in higher levels of on-chip integration and performance, higher current and power densities, increased leakage currents, and low-k dielectrics with poorer heat conductivity occur that present new challenges to package and heat dissipation designs.

CMOS power density is increasing. Recently the industry has seen it rise from 100 W/sq cm to 200 W/sq cm, beyond that of bipolar technology in the early 1990s. This increase in power density also increases the operating temperature of the device which materially interfered with proper operation of the device. The industry addressed this increase in operating temperature by securing the device to a heat exchange structure or material (i.e., heat-spreader), but different coefficients of expansion of the heat-spreader and the device caused structural and consequently further operating problems in the device. The difficulty was resolved for the most part by placing a thermal interface material (TIM) between the two that not only joined them in a heat exchange relation but also provided sufficient flexibility that enabled a link between the surfaces that substantially compensated for their different coefficients of expansions and substantially minimized any stress or strain placed on the device in the heat exchange process.

In summary, modern computer systems are built of discrete objects that must be electrically powered, and as a natural consequence, cooled. Increasingly, these discrete objects are themselves complex packages, with substantial heat loads. Recently the power density of computing systems has reached the point where liquid cooling is appropriate. In air-cooled systems, individual heat sinks can be attached to these discrete objects in a permanent way, and the low mass of these heat sinks does not adversely affect the mechanical integrity of the object cooled, nor the component's attachment to the circuit card. However, in a liquid cooled system, the mass of the cold plate can be substantially larger than the heat sink, requiring an external support system. Moreover, the cold plate may extend over several discrete packages. In either case, the thermal interface between cold plate and discrete component now needs to be separable for purposes of re-work, and the forces required to separate the interface cannot cause damage to the object to be cooled. This requirement can be difficult to meet.

A typical case involves an array of power-supply components, nominally of the same height h but with a height variation of Δh. Each component has substantial heat generation, requiring water cooling. The components, which have fragile internal solder connections, are mounted on a planar circuit card. A TIM is required to effectively transfer heat from the components to a cold plate that extends over the entire array of components. Damage to the fragile solder connections must be avoided both when the cold plate is attached, and also when it is removed. Removal is required for reworkability when a component fails. It must be replaced without damaging other good components, and replacement necessitates cold-plate removal. Consequently, there are two requirements to avoid damage:

(a) During cold-plate attachment, compressive stress no larger than σ₁ may be applied to any component's top surface, despite the height tolerance Δh. This implies that the TIM's compressive modulus must no be too great.

(b) During cold-plate removal, tensile stress no larger than σ₂ may be applied to any component's top surface. This implies that the TIM's adhesion to a components surface must not be too great.

For a representative case, typical values may be Δh=0.5 mm, σ₁=15 psi, σ₂=7 psi.

In many cases, curable-paste adhesive TIMs, although they satisfy requirement (a), fail to satisfy requirement (b). Conversely, TIMs such as thermal pads, although they satisfy requirement (b), fail to satisfy requirement (a). Greases and low-cross-link-density polymeric gels may satisfy both requirements (a) and (b), but they lack positional stability. Moreover, these materials suffer from pump-out the mechanical transfer of TIM material due to thermal-mechanical movement between the heat-spreader and the large printed circuit board that carries the components.

A positionally stable TIM that meets both requirements (a) and (b) is desired. Finding such a TIM is becoming increasingly problematic in the electronics industry. The present invention proposes a method for controlling TIM force for disassembly which would meet this and all other application requirements.

### RELATED ART

Schuette et al., U.S. Pat. No. 7,738,252; Furman, et al., U.S. Pat. No. 7,694,719; Gruendler et al., U.S. Pat. No. 7,688,592; Thompson et al., U.S. Pat. No. 7,646,608; Mok et al., U.S. Pat. No. 7,002,247; Solbrekken et al., U.S. Pat. No. 6,523,608; Edwards et al., U.S. Pat. No. 6,275,381; Lee et al. U.S. Pat. No. 6,050,832; Deeney, U.S. Pat. No. 5,783,862; Rhoades et al., U.S. Pat. No. 4,151,547; Hill et al. United States Patent Application Publication 2010/0321895; Pang TIM Selection Criteria for Silicon Validation Environment; 26th IEEE SEMI-THERM Symposium 2010, pp. 107 et seq. all show heat transfer devices for dissipating heat from a heat generating body.

### SUMMARY OF THE INVENTION

The present invention provides structures, articles of manufacture and processes that address these needs not only to provide advantages over the related art, but also to obviate substantially one or more of the foregoing and other limitations and disadvantages of the related art. The present invention provides a composite layered TIM to connect a heat-spreader to a heat-source, and especially a heat-source comprising a substrate having a plurality of components of different heights where the components also generate heat.

Not only do the written description, claims, and abstract of the disclosure set forth various features, objectives, and advantages of the invention and how they may be realized and obtained, but these features, objectives, and advantages will also become apparent by practicing the invention.

### BRIEF DESCRIPTION OF THE DRAWINGS

The accompanying drawings are not necessarily drawn to scale but nonetheless set out the invention, and are included to illustrate various embodiments of the invention, and together with this specification also serve to explain the principles of the invention. These drawings comprise various Figs. that illustrate, inter alia structures and methods for adjusting the bonding strength of adhesives such as TIMs to substrates.

FIGS. 1-10 Illustrate several aspects of the present invention comprising side elevations in cross-section of composite layered TIMs in various stages of assembly to connect a heat-spreader to a heat-source, and especially a heat-source comprising a substrate having a plurality of components of different heights where the components also generate heat.

### DETAILED DESCRIPTION OF THE INVENTION

To achieve the foregoing and other advantages, and in accordance with the purpose of this invention as embodied and broadly described herein, the following detailed description comprises disclosed examples of the invention that can be embodied in various forms.

The specific processes, compounds, compositions, and structural details set out herein not only comprise a basis for the claims and a basis for teaching one skilled in the art how to employ the present invention in any novel and useful way, but also provide a description of how to make and use this invention. The written description, claims, abstract of the disclosure, and the drawings that follow set forth various features, objectives, and advantages of the invention and how they may be realized and obtained. These features, objectives, and advantages will also become apparent by practicing the invention.

The invention comprises, among other things, a system in which a cold plate spans a plurality of heat-producing components, with a layer of a TIM between the cold plate and each component, and where the nominal height h of the components, comprising a range of about 0.5 to about 5.0 mm has a wide tolerance Δh (comprising a value of about +/−0.5 mm or more), leading to a similar variability Δh in the bond-line thickness of the TIM, and further where the components may be damaged by either excessive compressive stress or excessive tensile stress normal to the bonded surface. We provide a system that simultaneously meets two objectives: (a) low compressive stress normal to the bonded surface during assembly, (b) low tensile stress normal to the bonded surface during disassembly.

The TIM structure is comprised of a curable-paste adhesive TIM in series with a thin thermal pad-type TIM having little or no tack. The thermal pad-type TIM can be positioned onto either the heat-spreader or the component surface. Next, the curable-paste adhesive is applied to either the second surface or directly to the exposed surface of the thermal pad-type TIM. This combination of two TIM layers satisfies both requirements (a) and (b): the curable-paste adhesive satisfies requirement (a) by providing low compressive stress during assembly, while the low-tack thermal pad-type TIM satisfies requirement (b) because it separates easily from the abutting solid surface, thereby providing low tensile stress during disassembly. Moreover, this two-layer TIM is mechanically stable and will not pump out.

Pad-type TIMs can be designed to satisfy requirement (b), because a very broad range of adhesion, from very low (about <5 psi) to moderate (about >15 psi), can be achieved. However, pad-type TIMs alone are not compliant enough to satisfy requirement (a) under the typical condition Δh of about 0.5 mm. Even with smaller Δh, the pad-type TIM may, during assembly, need high compressive stress (about >10 psi) to achieve the target bondline for all components.

Conversely, curable-paste adhesives can easily satisfy requirement (a), accommodating a very broad range of bondlines. However, when cured, such adhesives will typically have adhesion stress far in excess of 10 psi, thereby violating requirement (b). Consequently, in order to achieve the favorable attributes and avoid the undesirable attributes of each class of TIM, thermal pad-type TIMs and paste adhesives may be used in series. This is the essence of the invention.

Another class of TIMs that could be used as a release layer with both low compressive mating and tensile removing forces is phase change TIMs. These materials typically melt between about 45 and about 65 C and in the melt state will allow low force separation. The advantage of these phase change TIMs over thermal pad-type TIMs is that the thermal resistance at the interface can be lower because a melt will more intimately contact the surfaces of a discrete component or heat-spreader better than a thermal pad-type TIM.

### DETAILED DESCRIPTION

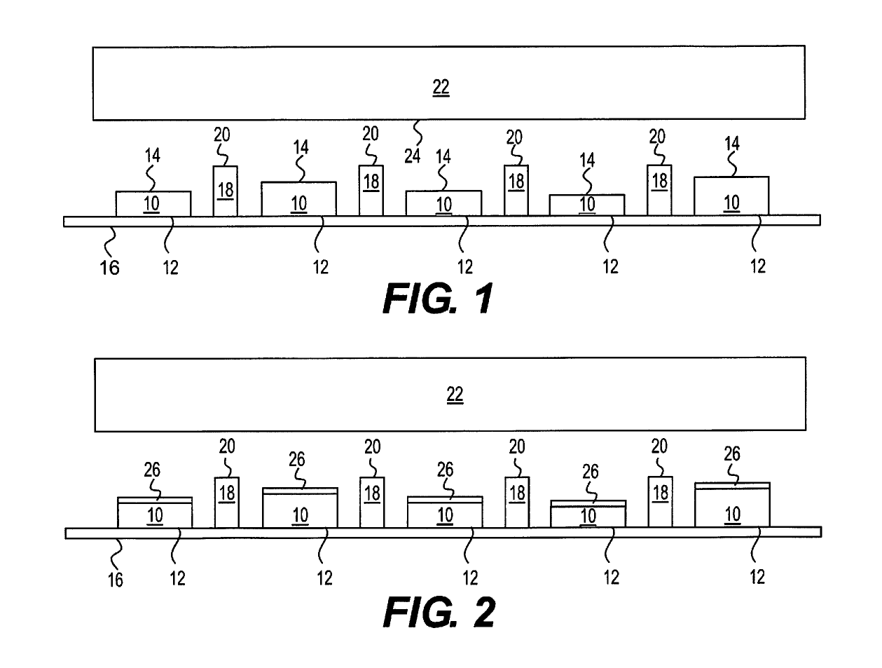

Referring to FIG. 1, a first embodiment comprises a plurality of heat-producing components 10, each having a lower surface 12 and an upper surface 14. The lower surface 12 of each heat-producing component 10 is affixed to a circuit card 16, but due to manufacturing and assembly tolerances, the upper surfaces 14 are not coplanar. Also affixed to the circuit card 16 is a plurality of stand-offs 18, each having an upper surface 20. All stand-off surfaces 20 are substantially coplanar. The first embodiment also comprises a cold plate 22 having a lower surface 24 that will be described later. Surface 24 abuts the coplanar surfaces 20 of stand-offs 18, thereby creating gaps between the non-coplanar upper surfaces 14 of the heat-producing components 10 and the planar lower surface 24 of the cold plate 22. These gaps will be filled with TIMs having relatively low thermal impedance, thereby creating as small a thermal impedance as possible between the non-coplanar surfaces 14 and the surface 24.

For this purpose, and referring to FIG. 2, the first embodiment also comprises a plurality of pad-type TIMs 26, which are applied to the top surfaces 14 of the heat-producing devices 10. Each pad-type TIM 26 substantially covers the corresponding upper surface 14.

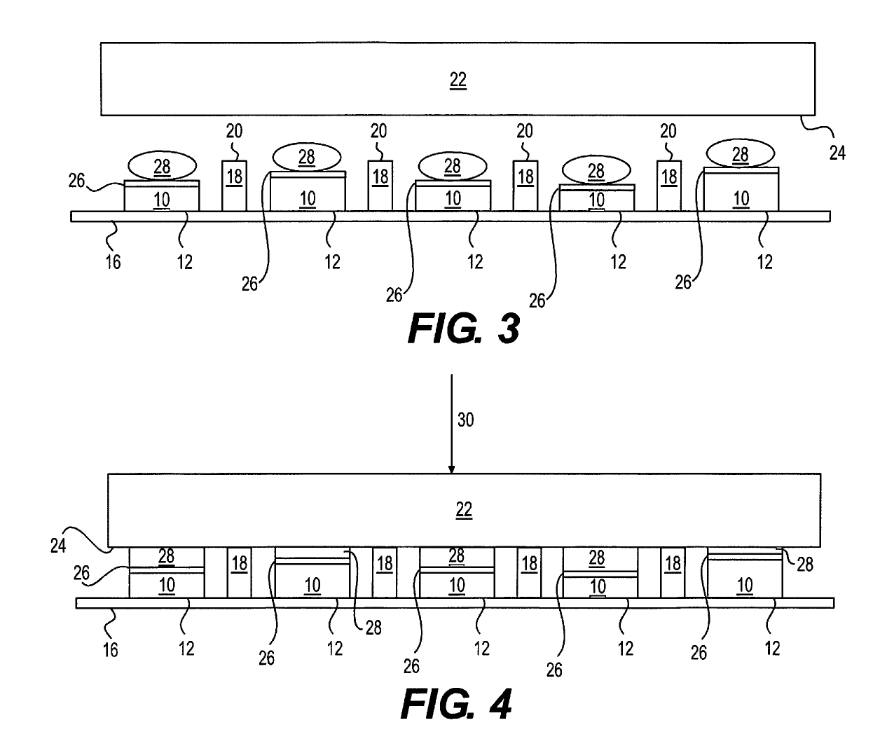

Referring to FIG. 3, the first embodiment further comprises a plurality of volumes of curable-adhesive TIMs 28 having a paste-like consistency, and having typically been dispensed onto the pad-type TIMs 26 from a tube or by other dispensing means.

Referring to FIG. 4, the first embodiment further comprises means to apply downward force 30 that moves the bottom surface 24 of cold plate 22 into contact with the top surfaces 20 of stand-offs 18. The cold plate 22 is affixed to the standoffs 18. The assembly process is complete. Because the curable-adhesive TIM 28 is a paste, the downward force 30 is modest and does not exceed the compressive-stress limitation of the heat-producing components 10.

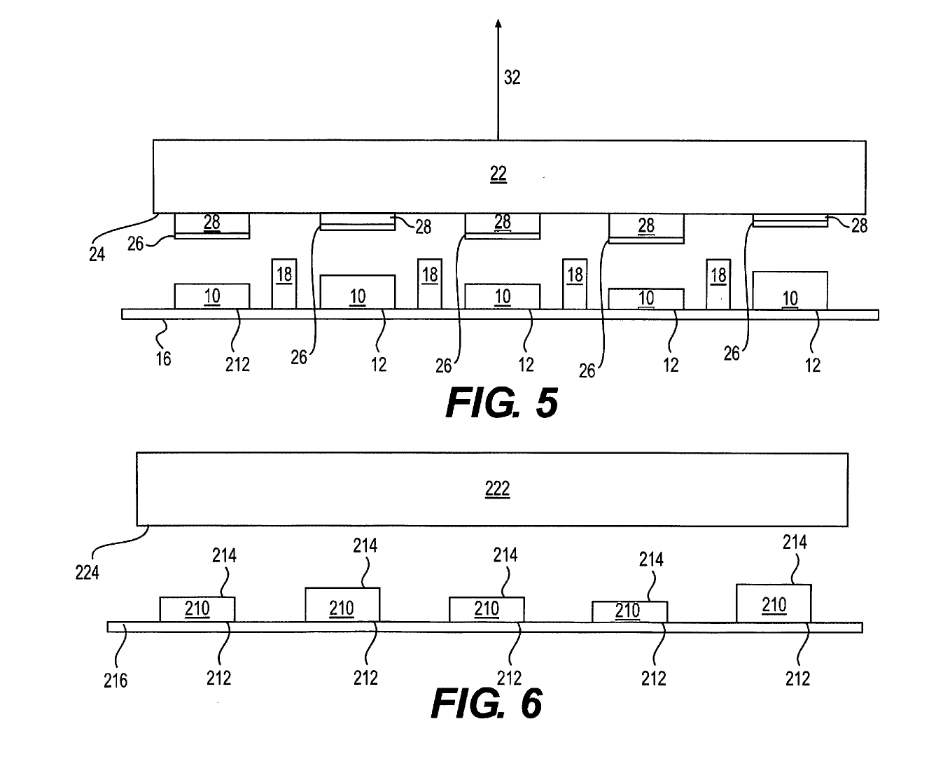

Referring to FIG. 5, after detaching the cold plate 22 from the standoffs 18, the first embodiment further comprises means to apply an upward force 32 that causes the cold plate 22 to be separated from the standoffs 18. The lower surface of the pad-type TIM 26 has very low tack, and is selected so as not to exceed the tensile-force limitation of the heat-producing components 10, thereby allowing upward force 32 to be modest when separating cold plate 22 from components 10.

In reducing the invention to practice and testing it, we found in the disassembly process represented by FIG. 5, adhesion testing of the bilayer TIM structure has consistently given adhesion at 33 to 50% of the value of the lowest strength (˜15-20 psi) curable-paste adhesive, thereby providing a useful solution to the problem of reworking force-sensitive, heat-producing components. In this disassembly step separation is engineered to occur between the pad-type TIM 26 and the components 10.

The second embodiment is similar to the first, except the two TIMs are reversed, i.e., the pad-type TIMs abut the cold plate, and we apply the paste TIM to the component that produces heat during operation. [0000] Referring to FIG. 6, the second embodiment comprises a plurality of heat-producing components 210, each having a lower surface 212 and an upper surface 214. The lower surface 212 of each heat-producing component 210 is affixed to a circuit card 216, but due to manufacturing and assembly tolerances, the upper surfaces 214 are not coplanar. The second embodiment also comprises a cold plate 222 having a lower surface 224 that will be described later.

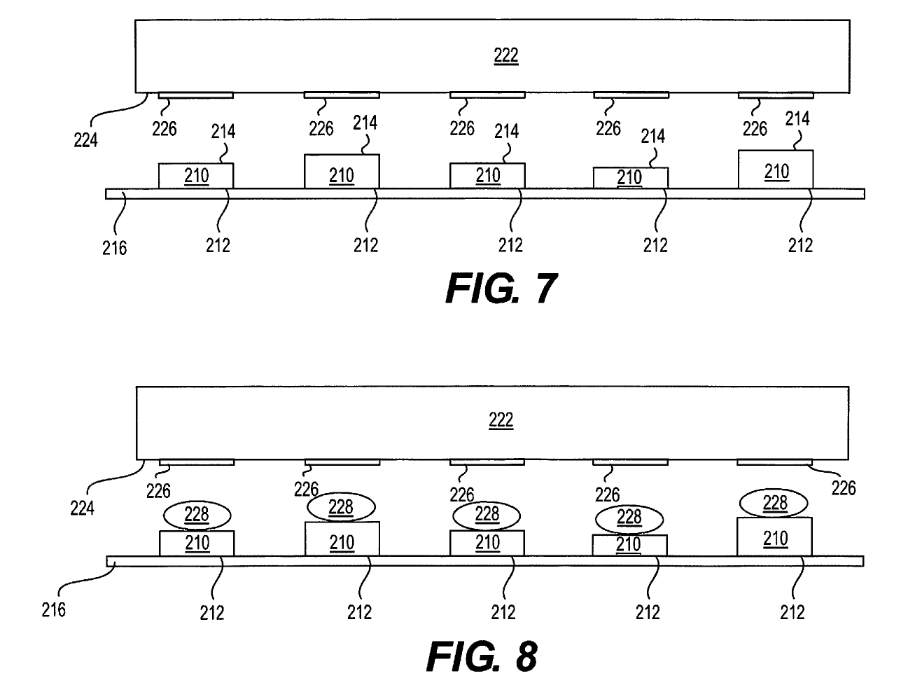

For this purpose, and referring to FIG. 7, the second embodiment also comprises a plurality of pad-type TIMs 226, which are applied to surface 224, each pad-type TIM 226 substantially aligned to project toward each upper surface 214.

Referring to FIG. 8, the second embodiment further comprises a plurality of volumes of curable-adhesive TIMs 228 having a paste-like consistency, and having typically been dispensed onto components 210 from a tube or by other dispensing means.

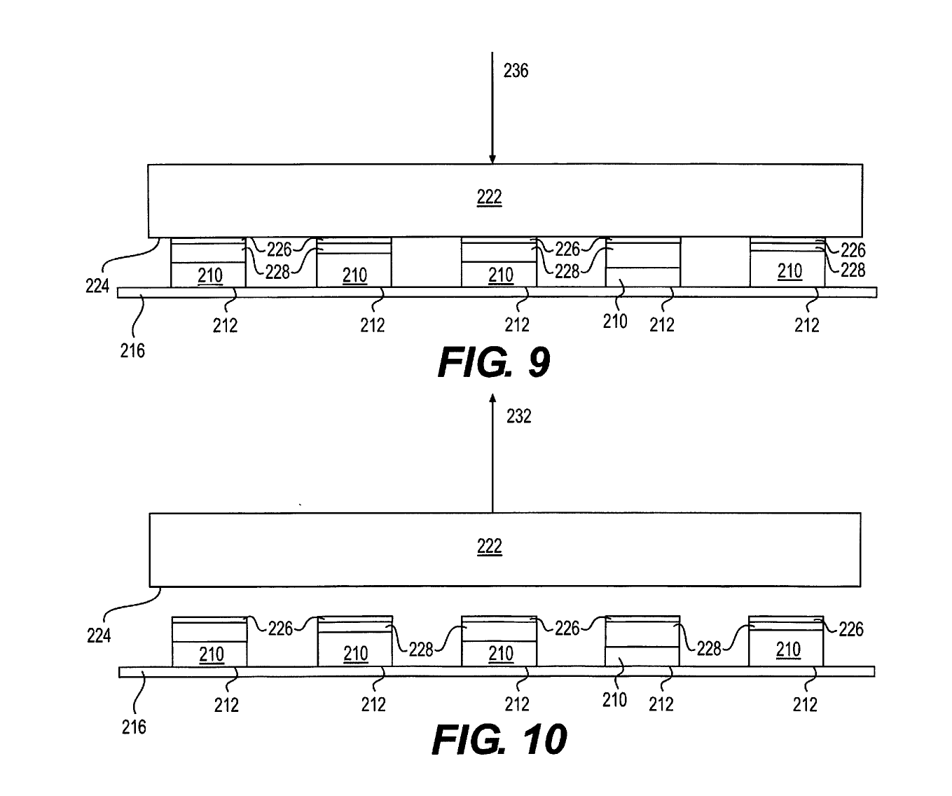

Referring to FIG. 9, the second embodiment further comprises means to apply downward force 230 that moves the bottom surface of pad-type TIMs 226 into contact with the top surfaces of curable-adhesive TIMs 228. The assembly process is complete. Because the curable-adhesive TIM 228 is a paste, the downward force 230 is modest and does not exceed the compressive-stress limitation of the heat-producing components 210.

Referring to FIG. 10, we detach the cold plate 222 from pad-type TIMs 226 by means of an upward force 232 that causes the cold plate 222 to be separated from pad-type TIMs 226. The upper surface of the pad-type TIM 226 has very low tack, and is selected so as not to exceed the tensile-force limitation of the heat-producing components 210, thereby allowing upward force 232 to be modest when separating cold plate 222 from TIMs 226.

Examples of Curable Paste TIMs Comprise:

1. Bergquist Gap Fillers that includes GF1500, GF2000, GF3500S35 and GF4000

2. Chomerics Therm-a-Fore™ T642, T644 and T647

Examples of Phase Change TIMs Comprise:

1. Honeywell PCM 45F SP

2. Bergquist Hi-Flow® 300 and 565

3. Laird T-pcm™ 583 and 585

Examples of Pad-Type TIMs Comprise:

1. Bergqust Gap Pad® 2500, 3000S30 and 5000S35

2. Laird T-pli™, T-flex™, and T-putty™

3. Chomerics Therm-a-Gap™ 569, 570, 579 and 580

4. Fujipoly Sarcon® Gap Filler Pads GR and XR Series

Examples of Curable Paste TIMs Comprise:

1. Bergquist Gap Fillers that includes GF1500, GF2000, GF3500S35 and GF4000

2. Chomerics Therm-a-Fore™ T642, T644 and T647

Examples of Phase Change TIMs Comprise

1. Honeywell PCM 45F SP

2. Bergquist Hi-Flow® 300 and 565

3. Laird T-pcm™ 583 and 585

Common Examples of Pad-Type TIMs Comprise:

1. Bergqust Gap Pad® 2500, 3000S30 and 5000S35

2. Laird T-pli™, T-flex™ and T-putty™

3. Chomerics Therm-a-Gap™ 569, 570, 579 and 580

4. Fujipoly Sarcon® Gap Filler Pads GR and XR Series

Throughout this specification, and abstract of the disclosure, the inventors have set out equivalents, of various materials as well as combinations of elements, materials, compounds, compositions, conditions, processes, structures and the like, and even though set out individually, also include combinations of these equivalents such as the two component, three component, or four component combinations, or more as well as combinations of such equivalent elements, materials, compositions conditions, processes, structures and the like in any ratios or in any manner.

Additionally, the various numerical ranges describing the invention as set forth throughout the specification also includes any combination of the lower ends of the ranges with the higher ends of the ranges, and any single numerical value, or any single numerical value that will reduce the scope of the lower limits of the range or the scope of the higher limits of the range, and also includes ranges falling within any of these ranges.

The terms “about,” “substantial,” or “substantially” as applied to any claim or any parameters herein, such as a numerical value, including values used to describe numerical ranges, means slight variations in the parameter or the meaning ordinarily ascribed to these terms by a person with ordinary skill in the art. In another embodiment, the terms “about,” “substantial,” or “substantially,” when employed to define numerical parameter include, e.g., a variation up to five per-cent, ten per-cent, or 15 per-cent, or somewhat higher. Applicants intend that terms used in the as-filed or amended written description and claims of this application that are in the plural or singular shall also be construed to include both the singular and plural respectively when construing the scope of the present invention.

All scientific journal articles and other articles, including internet sites, as well as issued and pending patents that this written description or applicants' Invention Disclosure Statements mention, including the references cited in such scientific journal articles and other articles, including internet sites, and such patents, are incorporated herein by reference in their entirety and for the purpose cited in this written description and for all other disclosures contained in such scientific journal articles and other articles, including internet sites as well as patents and the references cited therein, as all or any one may bear on or apply in whole or in part, not only to the foregoing written description, but also the following claims, and abstract of the disclosure.

Although we describe the invention by reference to some embodiments, other embodiments defined by the doctrine of equivalents are intended to be included as falling within the broad scope and spirit of the foregoing written description, and the following claims, abstract of the disclosure, and drawings.

We claim:

1. An article of manufacture comprising a thermally conductive composite material to conduct heat between a first surface and a second surface in which the adhesive strength between said composite and said first surface is not equal to the adhesive strength of said composite and said second surface.

2. An article of manufacture comprising a composite, layered, and compressible TIM differentially adhered to a heat-spreader surface and a heat-source surface, wherein the adhesive strength of said TIM to said heat-source surface is not equal to the adhesive strength of said TIM to said heat-spreader surface and said adhesive strength of said TIM to said heat-source surface and said adhesive strength of said TIM to said heat-spreader surface is adjusted so that said heat-spreader surface and said heat-source surface can be substantially separated without damaging said heat-source surface.

3. The article of manufacture of claim 2 wherein said heat-source surface comprises a plurality of non-coplanar component surfaces corresponding to a plurality of microcircuit elements, said component surfaces being adhered to said heat-spreader by said TIM, said TIM being compressively bonded to said component surfaces and to said heat-spreader, the bond strength of said TIM to said heat-spreader and said component surfaces being adjusted so that the application of a mechanical effort to said heat-spreader in a direction away from said component surfaces will substantially separate said heat-spreader from said component surfaces without damaging said microcircuit elements.

4. The article of manufacture of claim 3 wherein said TIM comprises a curable-paste TIM adhesive layer and a pad-type TIM.

5. The article of manufacture of claim 3 wherein said TIM comprises a curable-paste TIM adhesive layer and a pad-type TIM having low adhesive bonding strength to a surface.

6. The article of manufacture of claim 4 wherein said TIM comprises a curable-paste TIM adhesive layer and a pad-type TIM, and said pad-type TIM engages said microcircuit elements.

7. The article of manufacture of claim 4 wherein said TIM comprises a curable-paste TIM adhesive layer bonded to a pad-type TIM, and said pad-type TIM engages said heat-spreader surface.

8. The article of manufacture of claim 3 wherein said TIM comprises a curable-paste TIM adhesive layer and a phase-change TIM.

9. The article of manufacture of claim 4 wherein said TIM comprises a curable-paste TIM adhesive layer and a phase-change TIM, and wherein said phase-change TIM engages said microcircuit elements.

10. The article of manufacture of claim 4 wherein said TIM comprises a curable-paste TIM adhesive layer and a phase-change TIM, and wherein said phase-change TIM engages said heat-spreader surface.

11. The article of manufacture of claim 2 wherein said heat-spreader surface is separated from said heat-source surface by a plurality of posts extending from said heat-source surface to abut said heat-spreader surface, said posts all being substantially the same height and extending above the surface of the longest of said microcircuit elements.

12. A process for manufacturing a device comprising forming a composite, layered, and compressible TIM having substantially opposed surfaces with different adhesivity, positioning one said surface of said TIM on a heat-spreader surface and the other said surface of said TIM on a plurality of heat-source surface, wherein at least one of said heat-source surfaces or one of said heat-spreader surfaces comprises an uneven surface, compressively bonding said TIM to said heat-spreader surface and said heat-source surface, the adhesive strength of said TIM to said heat-spreader surface and said heat-source surface being adjusted so that said heat-spreader surface and said heat-source surface can be substantially separated without damaging said heat-source surface.

13. The process of claim 12 wherein said heat-source surfaces comprise microcircuit elements of different heights and adhered to said heat-spreader surface by said TIM, said TIM being compressively bonded to said microcircuit elements and said heat-spreader surface, the bond strength of said TIM to said heat-spreader and said microcircuit elements being adjusted so that the application of a mechanical effort to said heat-spreader in a direction away from said microcircuit elements will substantially separate said heat-spreader from said microcircuit elements without damaging said microcircuit elements.

14. The process of claim 13 wherein said TIM is compressively bonded to said microcircuit elements, said TIM being sufficiently yieldable so as not to damage said microcircuit elements.

15. The process of claim 14 wherein said TIM comprises a curable-paste TIM adhesive layer and a pad-type TIM.

16. The process of claim 14 wherein said TIM comprises a curable-paste TIM adhesive layer bonded to a pad-type TIM having low adhesive bonding strength to a surface.

17. The process of claim 15 wherein said TIM comprises a curable-paste TIM adhesive layer and a pad-type TIM, and wherein said pad-type TIM engages said microcircuit elements.

18. The process of claim 15 wherein said TIM comprises a curable-paste TIM adhesive layer and a pad-type TIM, and wherein said pad-type TIM engages said heat-spreader surface.

19. The process of claim 14 wherein said TIM comprises a curable-paste TIM adhesive layer and a phase-change TIM.

20. The process of claim 15 wherein said TIM comprises a curable-paste TIM adhesive layer and a phase-change TIM, and wherein said phase-change TIM engages said microcircuit elements.

21. The process of claim 15 wherein said TIM comprises a curable-paste TIM adhesive layer and a phase-change TIM, and wherein said phase-change TIM engages said heat-spreader surface.

22. The process of claim 13 wherein said heat-spreader surface is separated from said heat-source surface by a plurality of posts extending from said heat-source surface to abut said heat-spreader surface, said posts all being substantially the same height and extending above the surface of the longest of said microcircuit elements.
